(19) United States
(12) Patent Application Publication
(10) Pub. No.: US 2024/0339529 A1
(43) Pub. Date: Oct. 10, 2024

(54) Charge transfer device having an influx portion for clock frequencies from 100 MHz

(71) Applicant: ESPROS Photonics AG, Sargans (CH)

(72) Inventors: Beat DE COI, Maienfeld (CH); Chongqi YU, Bad Ragaz (CH)

(21) Appl. No.: 18/293,656

(22) PCT Filed: Jul. 29, 2022
(86) PCT No.: PCT/EP2022/071379

§ 371 Date: Jan. 30, 2024

(30) Foreign Application Priority Data
Aug. 2, 2021 (EP) 21189012.4

(51) Int. Cl. H01L 29/768

(52) U.S. Cl. CPC H01L 29/7685; H01L 29/76808

(57) ABSTRACT

A charge transfer device having a charge transfer channel in a semiconductor substrate. The charge transfer channel is formed by overlap of the possible electrostatic effect of the gates with the conduction layer. A clock generator has a clock frequency of more than 100 MHz which applies changes in potential at the clock frequency to the gates, for transporting charge carriers at the clock frequency from adjacent regions of the overlap between adjacent gates and the conduction layer. The charge transfer channel has an influx region which, in the flow direction, is arranged at a lateral outer boundary of the charge transfer channel and which at least partly extends over the regions of exactly two adjacent gates of the charge transfer channel in order to supply charge carriers to the charge transfer channel from a region outside the charge transfer channel that adjoins the influx region from a second charge transfer channel.

### CROSS-REFERENCES TO RELATED APPLICATIONS

This application is a Section 371 National Stage Application of International Application No. PCT/EP2022/071379, filed Jul. 29, 2022, and published as WO 2023/012066 A1 on Feb. 9, 2023, and claims priority to European Application No. 21189012.4 filed Aug. 2, 2021; the contents of these applications are hereby incorporated by reference in their entirety.

### BRIEF DESCRIPTION OF THE DRAWINGS

Exemplary embodiments are illustrated in the drawings and are explained in greater detail below. In this case, identical reference signs in the individual figures designate elements which correspond to one another.

FIG. 1 shows a conduction transfer channel in section along flow direction.

FIG. 2 shows a conduction transfer channel in section perpendicular to flow direction.

FIG. 3 shows a conduction transfer channel with constriction in plan view.

FIG. 4 shows a conduction transfer channel with protuberance in plan view.

FIG. 5 shows a conduction transfer channel with influx in plan view.

### DETAILED DESCRIPTION

The present disclosure relates to a semiconductor structure having a charge transfer channel for clock frequencies in the range starting from 100 MHz, preferably 250 MHz, particularly preferably up to 400 MHZ.

At clock frequencies of more than 100 MHZ, especially more than 250 MHz and in particular up to 400 MHz, losses may increasingly occur when transporting the charge carriers through a charge transfer channel.

It is an object of the present disclosure to provide improved charge transfer at clock frequencies of more than 100 MHz, preferably starting from 250 MHz, particularly preferably up to 400 MHz.

Proceeding from a semiconductor structure of the type mentioned in the introduction, the object is achieved by means of features described herein. Advantageous embodiments and developments of the present disclosure are possible by virtue of the measures mentioned herein.

The charge transfer device according to the present disclosure uses a charge carrier channel, inter alia. A charge transfer channel can be an overlap of the possible electrostatic effect of mutually adjoining gates with a conduction layer in a semiconductor. The charge transfer channel can thus be the intersection volume from the projection of the electrostatic effect of the gates onto the volume structure of the conduction layer.

The conduction layer, in which the charge carrier transport or charge carrier transfer takes place, can be situated in a semiconductor substrate and can be doped differently than the surrounding semiconductor substrate, with the result that charge carriers can move in the conduction layer and do not escape into the surrounding semiconductor substrate. A conduction layer can be buried or situated on the surface of the semiconductor substrate.

The gates can be electrodes which are arranged along the conduction layer and are separated from the conduction layer by a thin, nonconducting separating layer, with the result that a change in potential at the gates takes effect as a change in the electric field in the overlappingly assigned region of the conduction layer. The gates can be situated on the semiconductor substrate in a manner insulated by a thin separating layer.

Charge carriers can be electrons or holes.

Corresponding changes in potential at adjoining gates enable charge carriers to be transported in the charge transfer channel, with the result that the charge transfer channel can act as a conduction channel for a directional flow of charge carriers. The change in potential generally follows a clock frequency. The changes in potential can follow a clock frequency in this case. The clock frequency determines the rate of charge transport and thus the temporal resolution and performance of surrounding or connected systems such as sensors or computing units, for instance.

The boundaries, shape and course of the gates, the conduction layer and the charge transfer channel are always specified from the gates in the direction of the conduction layer in plan view, unless stated otherwise in an individual case. The course of the charge transfer channel and spatial relations are always specified in the direction of the charge carrier flow in the charge transfer channel, unless stated otherwise in an individual case.

If the width of the course of the juxtaposed gates is narrower than the width of the course of the assigned conduction layer, then the boundaries of the width of the course of the charge transfer channel are given by the boundaries of the course of the width of the juxtaposed gates. If the width of the course of the juxtaposed gates is wider than the width of the course of the assigned conduction layer, then the boundaries of the width of the course of the charge transfer channel are given by the boundaries of the course of the width of the assigned conduction layer.

It has been recognized in connection with the present disclosure that at relatively high clock frequencies starting from 150 MHz or 250 MHz, some of the charge carriers situated below a gate, in the event of a corresponding change in potential, often do not cross to the next gate as desired; advantageously, this effect can be reduced or avoided by means of the charge transfer device according to one example.

The charge transfer device according to one example is a charge transfer device having a charge transfer channel in a semiconductor substrate having a doped conduction layer for movably accepting the charge carriers, having a sequence of at least two electrically isolated gates which adjacently succeed one another for transferring the charge carriers in the conduction layer in a flow direction, wherein the charge transfer channel is formed by overlap of the possible electrostatic effect of the gates with the conduction layer, and having a clock generator having a clock frequency of more than 100 MHZ, in particular more than 150 MHz, more than 200 MHz or approximately or more than 250 MHz or up to 300 MHz or 400 MHZ, which applies changes in potential at the clock frequency to the gates, for transporting charge carriers at the clock frequency from adjacent regions of the overlap between adjacent gates and the conduction layer to adjacent regions of the overlap between adjacent gates and the conduction layer, which corresponds to the transport via a CCD structure, wherein the charge transfer channel has an influx region which, in the flow direction, is arranged at a lateral outer boundary of the charge transfer channel and which at least partly extends over the regions of exactly two adjacent gates of the charge transfer channel in order to supply charge carriers to the charge transfer channel from a region outside the charge transfer channel that adjoins the influx region, in particular from a second charge transfer channel, and in order in particular to reduce the spillback or the flow resistance or the loss of the charge carriers in the flow direction of the charge transfer channel or of the region supplying charge carriers to the charge transfer channel, in particular of a second charge transfer channel.

This charge transfer channel according to one example can afford the advantage that charge carriers can flow with less resistance and/or fewer losses.

Preferably, the length of the influx region along the conduction channel is less than the length of the region of the assigned two adjacent gates along the charge transfer channel and in particular corresponds to 25-95%, 35-85%, 45-75%, 55-65%, or 60% of the length of the region of the assigned two adjacent gates along the charge transfer channel, in order to enable the charge carriers to be transferred from gate to gate as losslessly as possible.

Furthermore, the following measures can also be implemented for the reduction of the losses:

Preferably, the influx region with its length along the conduction transfer channel adjoins (in an offset manner) the region of the assigned gate situated counter to the flow direction over a greater length than the region of the assigned gate situated in the flow direction and in particular adjoins the region of the assigned gate situated counter to the flow direction to the extent of more than 50%, more than 60%, between 60% and 75%, or ⅔.

Preferably, the influx region has a protuberance in which the cross-section with respect to the flow direction first increases (in particular by more than 20%, 40%, 80% or 100%) and then decreases again (in particular by more than 20%, 40%, or 80%), which extends in terms of its length in the flow direction at least, substantially or exactly over the influx region, wherein the length of the protuberance in the flow direction is less than the width of the increase in the cross-section, in particular less than 50%, less than 25%, or less than 12%, and wherein the protuberance is substantially rectangular, in particular.

Preferably, the charge transfer channel has a region of a constriction in which the cross-section decreases in the flow direction and which is arranged counter to the flow direction upstream of the influx location and at least partly in the region of the one assigned gate situated counter to the flow direction and is embodied in particular as beveled and/or funnel-shaped in order in particular to reduce the spillback or the flow resistance or the loss of the charge carriers in the flow direction.

Preferably, the semiconductor substrate is p+ doped and/or the conduction layer is weakly n-doped and/or the gates are formed from metal and/or a nonconducting layer is arranged between the gates and the conduction layer and/or the gates are separated in a manner electrically insulated from one another.

FIG. 1 shows a charge transfer channel 10 in side view along the flow direction 31 of the charge carriers in the following figures. The construction is analogous to CCD technology. The surrounding semiconductor substrate 20 is p+ doped. A buried conduction layer 30 is arranged in the semiconductor substrate 20. The conduction layer is weakly n-doped. This has the consequence that electrons as charge carriers are freely mobile in the conduction layer and do not penetrate into the semiconductor substrate. An insulation layer 43 is applied on the conduction layer and gates 40, 41, 50 composed of metal are arranged on said insulation layer. The gates are electrically isolated from one another by interspaces. The clock generator (not illustrated) applies a positive potential at a clock frequency of 250 MHz alternately to the adjacent gates, with the result that conduction electrons in the conduction layer are attracted from one gate to the next and are thus transferred in the flow direction. The clock frequency could also be only more than 100 MHz, more than 150 MHz or more than 200 MHz. In general, the clock frequency is not higher than 300 MHz. The conduction electrons can be for example photoinduced electrons from an image sensor connected to the conduction channel.

The semiconductor substrate 20 is p+ doped and the conduction layer 30 is n-doped. The insulation layer 43 is composed of SiO2 and the gates are formed from metal.

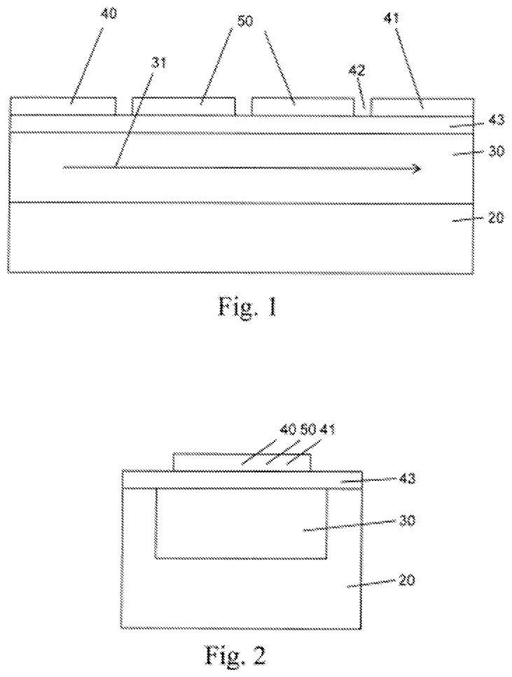

FIG. 2 shows the charge transfer channel in side view perpendicular to the flow direction of the charge carriers in the following figures. The conduction layer 30 is buried, and so it is encompassed from above and laterally by the semiconductor substrate 20. Semiconductor substrate 20 and conduction layer 30 are provided with an insulation layer toward the top. The gates 40, 41, 50 are arranged on the insulation layer 43 in the region above the conduction layer 30. The gates are embodied as narrower than the conduction layer in the width extent along the flow direction.

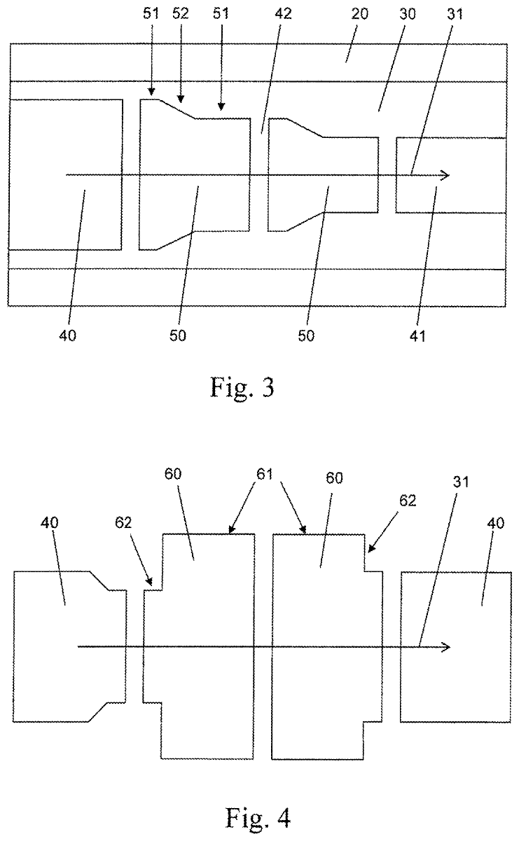

FIG. 3 shows a charge transfer channel in plan view. The conduction layer 30 is embedded in the semiconductor substrate 20. The overlying insulation layer is not shown. Above the region of the conduction layer 30, in a manner separated by the insulation layer (not shown), the gates 40, 50, 41 are arranged in an electrically isolated manner in flow direction 31 of the electrons and with spacings 42. Overall, the gates exhibit a constriction of the cross-section in the flow direction. The first gate 40 has a wide cross-section, while the last gate 41 has a comparatively narrower cross-section. The two gates 50 have a narrowing cross-section in flow direction 31. The narrowing gate 50 has, in flow direction 31, firstly a wide region with constant cross-section without constriction 51, then a cross-sectionally narrowing region with constriction 52 and thereupon a narrower region with once again constant cross-section without constriction 51. In this case, the gate 50 has regions with constant cross-section at the transition to the adjacent gates. The region arranged counter to the flow direction with constant cross-section without constriction is shorter than the region arranged in the flow direction with constant cross-section without constriction. As a result, the narrowing region with constriction 52 is arranged in a manner displaced from the center of the gate 50 counter to the direction of the flow direction. The narrowing region with constriction 52 is embodied as beveled on both sides, with the result that it has a funnel-shaped shape. The embodiment of a constriction thus shown makes it possible to minimize the spillback and/or the flow resistance and/or the losses of the charge carriers in the flow direction.

FIG. 4 shows the gates of a charge transfer channel in plan view. The conduction layer situated below the gates is not illustrated. The maximum width of the gates 40 situated at the beginning and end of the gate sequence shown in the flow direction forms the typical width of the cross-section of the conduction transfer channel. By contrast, the two gates 60 have a continuous region of a protuberance 61, in the case of which the cross-section is enlarged by the width 62 approximately 25% in comparison with the typical width. Directly at the protuberance, the first gate 60 having the protuberance has a constriction 62, at which the cross-section of the charge transfer channel is narrower in comparison with the typical width. As a result, the entry into the protuberance is narrower than the exit from the protuberance. The constriction 62 is already embodied at the preceding gate 40 in the flow direction, which gate, by virtue of a funnel-shaped region, reduces the cross-section from the typical cross-section to the reduced cross-section of the constriction. The embodiment of a protuberance thus shown makes it possible to minimize the spillback and/or the flow resistance and/or the losses of the charge carriers in the flow direction.

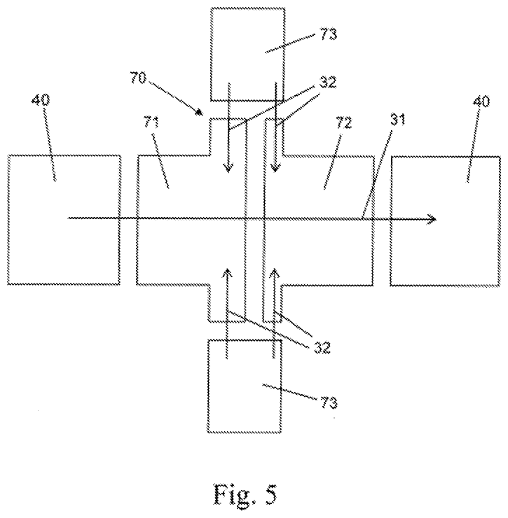

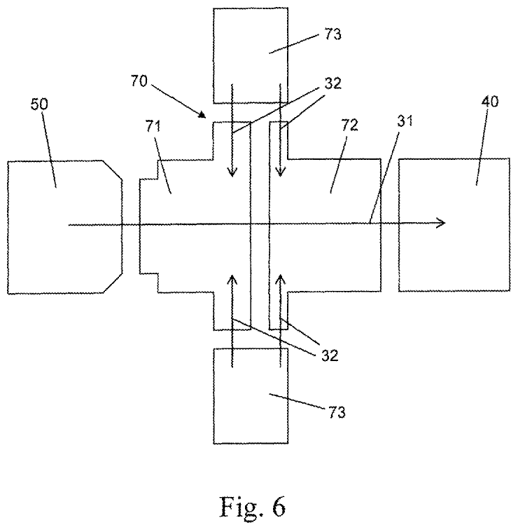

FIG. 5 shows the arrangement of the gates of a conduction transfer channel with a right and a left lateral influx region 70 in plan view. A first charge transfer channel is formed by the sequence of the gates 40, 71, 72 and 40 in flow direction 31 of the charge carriers. The conduction layer situated below the gates is not illustrated. The gates 71 and 72 have protuberances perpendicular to the flow direction in the direction of the gates 73, at which the first charge transfer channel has an increased cross-section in relation to the previous and succeeding gates 40. A second charge transfer channel is formed by the sequence of the gates 73 to 71 and 72 in each case on the right and left of the first charge transfer channel in flow direction 32 of the charge carriers. The charge carriers of the second charge carrier channels flow from the gate 73 partly into the gate 71 and partly into the gate 72 in order then to move further together with the charge carriers of the first charge carrier transfer channel in the flow direction 31 thereof. The influx region 70 is formed by the transition between the first gate 73 of the second charge transfer channel outside the first charge transfer channel and the two adjoining gates 71 and 72 of the first charge transfer channel. The cross-section of the influx region 70 corresponds to approximately 60% of the length of the two adjoining gates 71 and 72 in the flow direction. Overall, ⅔ of the influx region overlaps the adjoining gate 71 of the first charge transfer channel that is situated counter to the flow direction 31, and ⅓ of the influx region overlaps the adjoining gate 72 of the first charge transfer channel that is situated in the flow direction 31. Consequently, the influx region is displaced counter to the flow direction 31 in relation to the two adjoining gates of the first charge transfer channel. The embodiment of an influx region thus shown makes it possible to minimize the spillback and/or the flow resistance and/or the losses of the charge carriers in the flow direction.

FIG. 6 shows the arrangement from FIG. 5 with the first gate 50 having a constriction. The embodiment of an influx region thus shown makes it possible to further minimize the spillback and/or the flow resistance and/or the losses of the charge carriers in the flow direction.

Although the present invention has been described with reference to preferred embodiments, workers skilled in the art will recognize that changes may be made in form and detail without departing from the spirit and scope of the invention.

### LIST OF REFERENCE SIGNS

10 Charge transfer channel
20 Semiconductor substrate
30 Conduction layer
31 Flow direction
32 Flow direction
40 Gate, wide
41 Gate, narrow
42 Insulating spacing between the gates
43 Insulation layer
50 Gate with constriction
51 Region without constriction
52 Region with constriction
60 Gate with protuberance
61 Region with protuberance
62 Width of the protuberance
62 Constriction
70 Influx region
71 First gate of the first conduction channel with influx region
72 Second gate of the first conduction channel with influx region
73 Gate of a further conduction channel

1. A charge transfer device
having a charge transfer channel in a semiconductor substrate
having a doped conduction layer
for movably accepting the charge carriers,
having a sequence of at least two electrically isolated gates
which adjacently succeed one another
for transferring the charge carriers in the conduction layer in a flow direction,
wherein the charge transfer channel is formed by overlap of the possible electrostatic effect of the gates with the conduction layer, and
and having a clock generator
having a clock frequency of more than 100 MHZ,
which applies changes in potential at the clock frequency to the gates,
for transporting charge carriers at the clock frequency from adjacent regions of the overlap between adjacent gates and the conduction layer to adjacent regions of the overlap between adjacent gates and the conduction layer,
wherein
the charge transfer channel has an influx region
which, in the flow direction, is arranged at a lateral outer boundary of the charge transfer channel and
which at least partly extends over the regions of exactly two adjacent gates of the charge transfer channel
in order to supply charge carriers to the charge transfer channel from a region outside the charge transfer channel that adjoins the influx region from a second charge transfer channel, and
in order to reduce the spillback or the flow resistance or the loss of the charge carriers in the flow direction of the charge transfer channel or of the region supplying charge carriers to the charge transfer channel of a second charge transfer channel.

2. The charge transfer channel as claimed in claim 1, wherein
the length of the influx region along the conduction channel
is less than the length of the region of the assigned two adjacent gates along the charge transfer channel and
corresponds to 25-95% of the length of the region of the assigned two adjacent gates along the charge transfer channel.

3. The charge transfer channel as claimed in claim 1, wherein
the influx region
with its length along the conduction transfer channel
adjoins in an offset manner the region of the assigned gate situated counter to the flow direction over a greater length than the region of the assigned gate situated in the flow direction and
adjoins the region of the assigned gate situated counter to the flow direction to the extent of more than 50%.

4. The charge transfer channel as claimed in claim 1, wherein
the influx region
has a protuberance
in which the cross-section with respect to the flow direction first increases by more than 20% and then decreases by more than 20%,
which extends in terms of its length in the flow direction at least, substantially or exactly over the influx region,
wherein the length of the protuberance in the flow direction is less than the width of the increase in the cross-section less than 50%,
wherein the protuberance is substantially rectangular.

5. The charge transfer channel as claimed in claim 1, wherein
the charge transfer channel has a region of a constriction
in which the cross-section decreases in the flow direction and
which is arranged counter to the flow direction upstream of the influx location and
at least partly in the region of the one assigned gate situated counter to the flow direction and
is embodied as beveled and/or funnel-shaped
in order to reduce the spillback or the flow resistance or the loss of the charge carriers in the flow direction.

6. The charge transfer channel as claimed in claim 1, wherein
the semiconductor substrate is p+ doped, and/or
the conduction layer is weakly n− doped, and/or
the gates are formed from metal, and/or
a nonconducting layer is arranged between the gates and the conduction layer, and/or
the gates are separated in a manner electrically insulated from one another.

7. The charge transfer channel as claimed in claim 1, wherein the clock frequency is more than 150 MHz.

8. The charge transfer channel as claimed in claim 7, wherein the clock frequency is more than 200 MHz.

9. The charge transfer channel as claimed in claim 8, wherein the clock frequency is more than 250 MHz.

10. The charge transfer channel as claimed in claim 9, wherein the clock frequency is more than 300 MHz.

11. The charge transfer channel as claimed in claim 10, wherein the clock frequency is more than 400 MHz.

12. The charge transfer channel as claimed in claim 2, wherein the length of the influx region along the conduction channel corresponds to 35-85% of the length of the region of the assigned two adjacent gates along the charge transfer channel.

13. The charge transfer channel as claimed in claim 2, wherein the length of the influx region along the conduction channel corresponds to 45-75% of the length of the region of the assigned two adjacent gates along the charge transfer channel.

14. The charge transfer channel as claimed in claim 2, wherein the length of the influx region along the conduction channel corresponds to 55-65% of the length of the region of the assigned two adjacent gates along the charge transfer channel.

15. The charge transfer channel as claimed in claim 2, wherein the length of the influx region along the conduction channel corresponds to 60% of the length of the region of the assigned two adjacent gates along the charge transfer channel.

16. The charge transfer channel as claimed in claim 3, wherein the influx region adjoins the region of the assigned gate situated counter to the flow direction to the extent of more than 60%.

17. The charge transfer channel as claimed in claim 3, wherein the influx region adjoins the region of the assigned gate situated counter to the flow direction to the extent of between 60% and 75%.

18. The charge transfer channel as claimed in claim 3, wherein the influx region adjoins the region of the assigned gate situated counter to the flow direction to the extent of more than two-thirds.

19. The charge transfer channel as claimed in claim 4, wherein the length of the protuberance in the flow direction is less than the width of the increase in the cross-section less than 25%.

20. The charge transfer channel as claimed in claim 4, wherein the length of the protuberance in the flow direction is less than the width of the increase in the cross-section less than 12%.
